(19) United States
(12) Patent Application Publication
(10) Pub. No.: US 2016/0087124 A1
(43) Pub. Date: Mar. 24, 2016

(54) SOLAR CELL INCLUDING ELECTRODE FORMED ON HIGH SHEET RESISTANCE WAFER

(71) Applicant: SAMSUNG SDI CO., LTD., Yongin-si (KR)

(72) Inventors: Sang Hee PARK, Uiwang-si (KR); Hyun Jin KOO, Uiwang-si (KR); Tae Joon KIM, Uiwang-si (KR); Min Su PARK, Uiwang-si (KR); Myung Sung JUNG, Uiwang-si (KR); Hyun Jin HA, Uiwang-si (KR)

(21) Appl. No.: 14/821,824

(22) Filed: Aug. 10, 2015

(30) Foreign Application Priority Data
Sep. 23, 2014 (KR) 10-2014-0127062

(51) Int. Cl. H01L 31/0224; H01L 31/0236; H01L 31/068; H01L 31/0216

(52) U.S. Cl. CPC H01L 31/022466; H01L 31/02168; H01L 31/02363; H01L 31/068

(57) ABSTRACT

A solar cell, including a p-n junction substrate; and an electrode on one surface of the p-n junction substrate. The p-n junction substrate may have a sheet resistance of about 85 Ω/sq to about 150 Ω/sq, and a silver (Ag) crystal having a particle diameter of about 10 nm to about 1,000 nm may be present within the electrode adjacent to an interface between the p-n junction substrate and the electrode.

### CROSS-REFERENCE TO RELATED APPLICATION

Korean Patent Application No. 10-2014-0127062, filed on Sep. 23, 2014, in the Korean Intellectual Property Office, and entitled: “Solar Cell Including Electrode Formed on High Sheet Resistance Wafer,” is incorporated by reference herein in its entirety.

### BACKGROUND

1. Field

Embodiments relate to a solar cell including an electrode formed on a high sheet resistance wafer.

2. Description of the Related Art

Solar cells may generate electric energy using the photovoltaic effect of a p-n junction which may convert photons of sunlight into electricity. In the solar cell, front and rear electrodes may be formed on upper and lower surfaces of a semiconductor wafer or substrate with the p-n junction, respectively. Then, the photovoltaic effect of the p-n junction may be induced by sunlight entering the semiconductor wafer and electrons generated by the photovoltaic effect of the p-n junction may provide electric current to the outside through the electrodes. The electrodes of the solar cell may be formed on the wafer by applying, patterning, and baking a composition for electrodes.

### SUMMARY

Embodiments may be realized by providing a solar cell, including a p-n junction substrate; and an electrode on one surface of the p-n junction substrate. The p-n junction substrate may have a sheet resistance of about 85 Ω/sq to about 150 Ω/sq, and a silver (Ag) crystal having a particle diameter of about 10 nm to about 1,000 nm may be present within the electrode adjacent to an interface between the p-n junction substrate and the electrode.

The solar cell may further include an anti-reflection film and a front electrode sequentially formed on a front surface of the p-n junction substrate; and a back surface field layer and a rear electrode sequentially formed on a back surface of the p-n junction substrate.

The p-n junction substrate may include one surface of a p-type substrate doped with an n-type dopant to form an n-type emitter.

The p-n junction substrate may include one surface of an n-type substrate doped with a p-type dopant to form a p-type emitter.

The p-n junction substrate may have a textured structure on a front surface thereof.

The electrode may be prepared from a composition for solar cell electrodes, the composition including silver (Ag) powder; a glass fit containing elemental silver (Ag) and elemental tellurium (Te); and an organic vehicle, a mole ratio of Ag to Te ranging from about 1:0.1 to about 1:25 in the glass frit.

The elemental silver (Ag) may originate from at least one silver compound selected from a silver cyanide, silver nitrate, silver halide, silver carbonate, silver sulfate, and silver acetate.

The glass fit may contain about 0.1 mole % to about 50 mole % of the elemental silver (Ag) based on a total mole of the glass fit.

The glass frit may have an average particle diameter (D50) of about 0.1 μm to about 10 μm.

### BRIEF DESCRIPTION OF THE DRAWINGS

Features will become apparent to those of skill in the art by describing in detail exemplary embodiments with reference to the attached drawings in which:

FIG. 1 illustrates a schematic view of a solar cell according to one embodiment;

FIG. 2 illustrates a schematic view of a solar cell according to an embodiment;

FIG. 3 illustrates Table 1 listing compositions for solar cell electrodes prepared according to Examples 1-7 and Comparative Example 1;

FIG. 4 illustrates a scanning electronic microscope (SEM) image of a silver crystal formed within an electrode on a high sheet resistance wafer having a sheet resistance of 92.3 Ω/sq, in which the electrode was formed of a composition prepared in Example 1; and

FIG. 5 illustrates an SEM image of a silver crystal formed within an electrode on a high sheet resistance wafer having a sheet resistance of 100.5 Ω/sq, in which the electrode was formed of the composition prepared in Example 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Solar Cell

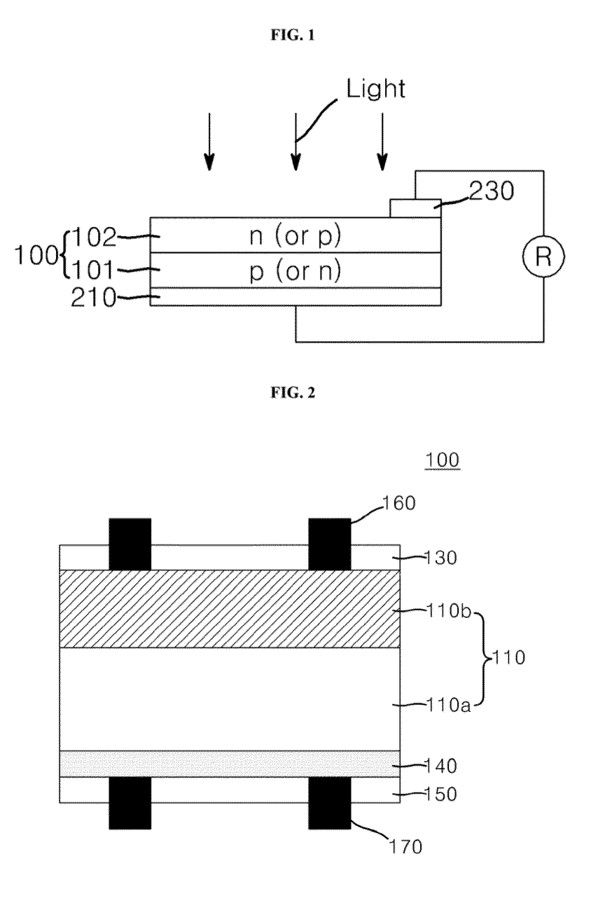

FIG. 1 illustrates a schematic view of a solar cell according to one embodiment. Referring to FIG. 1, a solar cell according to one embodiment may include a p-n junction substrate 100, a front electrode 230 formed on a front surface of the p-n junction substrate 100, and a rear electrode 210 formed on a back surface of the p-n junction substrate 100, wherein the p-n junction substrate 100 includes a p-layer (or n-layer) 101 and an n-layer (or p-layer) 102, which will serve as an emitter.

As used herein, the p-n junction substrate may refer to a substrate wherein one surface of a p-type substrate may be doped with an n-type dopant to form an n-type emitter, and providing a p-n junction, or a substrate wherein one surface of an n-type substrate may be doped with a p-type dopant to form a p-type emitter, and providing a p-n junction.

For example, a substrate 100 may have a front surface receiving incident light and a back surface opposite the front surface, and may be formed of a monocrystalline or polycrystalline silicon semiconductor or a compound semiconductor. When a crystalline silicon semiconductor is used, the substrate may be a silicon wafer. As the substrate 100, a p-type substrate doped with a p-type dopant may be used. In an embodiment, an n-type substrate doped with an n-type dopant may be used as the substrate. The p-type dopant may be, for example, a material including a group III element such as boron (B), aluminum (Al) or gallium (Ga), and the n-type dopant may be, for example, a material including a group V element, such as phosphorus (P), arsenic (As) or antimony (Sb).

The p-n junction substrate 100 according to one embodiment may be a substrate having high sheet resistance, and, for example, may have a sheet resistance of about 85 Ω/sq to about 150 Ω/sq.

The electrodes 210, 230 formed on the front or back surface of the p-n junction substrate 100 may be formed by printing and baking a composition for solar cell electrodes described below.

In the solar cell electrodes according to one embodiment, a silver crystal may be formed adjacent to an interface between the electrode and the p-n junction substrate, and may have a particle diameter of about 10 nm to about 1,000 nm. Within this range, it may be possible to minimize serial resistance even on a high sheet resistance substrate, and to provide excellent fill factor and conversion efficiency while securing stability of the p-n junction given varying sheet resistance.

FIG. 2 illustrates a schematic view of a solar cell according to an embodiment. Referring to FIG. 2, the solar cell according to this embodiment may include: a p-n junction substrate 110 obtained by forming an emitter 110b on a front surface of a substrate 110a; an anti-reflection film 130 and a front electrode 160 sequentially formed on a front surface of the p-n junction substrate 110; and a back surface field layer 140, an anti-reflection film 150, and a rear electrode 170 sequentially formed on a back surface of the p-n junction substrate 110. Hereinafter, for convenience of explanation, each component will be described with an assumption that the substrate 110a is a p-type substrate.

One surface of the p-type substrate 110a may be doped with an n-type dopant to form the n-type emitter 110b, and a p-n junction may be formed at an interface therebetween, and electrons generated in the p-n junction may be easily collected by the front electrode 160.

The p-n junction substrate 110 may have a textured structure on a front surface thereof. The textured structure may be formed by surface treatment of the front surface of the p-n junction substrate 110 using a method known in the art, such as etching. The textured structure may serve to reduce reflectance of light entering the front surface of the substrate and to condense the light, and may have, for example, a pyramidal shape, a square honeycomb shape, and a triangular honeycomb shape, and the textured structure may allow an increased amount of light to reach the p-n junction at the interface between the p-type substrate and the emitter, while minimizing optical loss.

The p-type substrate may be formed on a back surface thereof with a back surface field (BSF) layer 140 capable of inducing back surface field (BSF) effects.

The back surface field layer 140 may be formed by doping the back surface of the p-type substrate with a p-type dopant, and may make it difficult for electrons to shift towards the back surface of the p-type substrate by providing a potential difference resulting from a difference in concentration of the dopant so as to prevent recombination with metals in the back surface of the p-type substrate, and solar cell efficiency may be improved, for example, through an increase in open circuit voltage (Voc) and fill factor.

The anti-reflection films 130, 150 may be formed on an upper surface of the n-type emitter 110b and on a lower surface of the back surface field layer 140, respectively.

The anti-reflection film 130 may be formed on the front surface of the p-n junction substrate 110 disposed to receive sunlight, and may reduce reflectance of light while increasing selectivity with respect to a specific wavelength region. The anti-reflection film may enhance contact efficiency with silicon present on the front surface of the p-n junction substrate 110 to improve solar cell efficiency. The anti-reflection film 130 may include a material that may reflect less light and may exhibit electric insulation, for example, oxides including aluminum oxide (Al₂O₃), silicon oxide (SiO₂), titanium oxide (TiO₂ or TiO₄), magnesium oxide (MgO), cerium oxide (CeO₂), or combinations thereof; nitrides including aluminum nitride (AlN), silicon nitride (SiNₓ), titanium nitride (TiN) or combinations thereof; and oxynitrides including aluminum oxynitride (AlON), silicon oxynitride (SiON), titanium oxynitride (TiON), or combinations thereof, and may have a mono- or multi-layer structure.

Unlike a comparative method of forming a back surface field layer using an aluminum paste, when boron (B) doping is performed to form the back surface field layer, the anti-reflection film 150 may be additionally formed. The anti-reflection film 150 may further enhance open circuit voltage.

The anti-reflection films 130, 150 may be formed of, for example, silicon nitride (SiNₓ), by plasma enhanced chemical vapor deposition (PECVD). The anti-reflection films may be formed of silicon nitride (SiNₓ) by PECVD, or may be formed of aluminum oxide (Al₂O₃) by atomic layer deposition (ALD).

Next, the front electrode 160 electrically connected to the n-type emitter layer and the rear electrode 170 electrically connected to the p-type substrate may be formed. The front electrode 160 may electrically communicate with the n-type emitter layer and may allow electrons collected by the n-type emitter to move thereto. The rear electrode 170 may electrically communicate with the p-type substrate and may serve as a path through which electric current may flow.

For example, a preliminary process of preparing the rear electrode may be performed by printing a composition for solar cell electrodes on the back surface of the p-n junction substrate, followed by drying at about 200° C. to about 400° C. for about 10 seconds to 60 seconds. A preliminary process for preparing the front electrode may be performed by printing the composition for electrodes on the front surface of the p-n junction substrate, followed by drying the printed composition. Then, the front electrode and the rear electrode may be formed by baking at about 400° C. to about 950° C., for example, at about 750° C. to about 950° C., for about 30 seconds to 180 seconds.

By forming the front electrode or the rear electrode using a composition for solar cell electrodes described below, it may be possible to improve fill factor and conversion efficiency through synergistic effects between high open circuit voltage (Voc) of the p-n junction substrate having high sheet resistance and low contact resistance (Rc) and serial resistance (Rs) of the composition for solar cell electrodes including a glass fit originating from a silver compound that may decompose into silver (Ag) ions at a temperature of 1000° C. or less.

Composition for Solar Cell Electrodes

The composition for solar cell electrodes may include: silver (Ag) powder (A); glass frits originating from a silver compound (B); and an organic vehicle (C). Each component of the composition for solar cell electrodes will be described in more detail.

(A) Silver Powder

The composition for solar cell electrodes may include silver (Ag) powder as a conductive powder. The particle size of the silver powder may be on a nanometer or micrometer scale. For example, the silver powder may have a particle size of dozens to several hundred nanometers, or several to dozens of micrometers. In an embodiment, the silver powder may be a mixture of two or more types of silver powders having different particle sizes.

The silver powder may have a spherical, flake or amorphous shape.

In one embodiment, the silver powder may have an average particle diameter (D50) of about 0.1 μm to about 10 μm, for example, 0.5 μm to 5 μm. The average particle diameter may be measured using, for example, a Model 1064LD (CILAS Co., Ltd.) after dispersing the conductive powder in isopropyl alcohol (IPA) at 25° C. for 3 minutes via ultrasonication. Within this average particle diameter range, the composition may provide low contact resistance and low line resistance.

The silver powder may be present in an amount of about 60% by weight (wt %) to about 95 wt % based on the total weight of the composition. Within this range, the conductive powder may prevent deterioration in conversion efficiency, for example, due to increase in resistance and difficulty in forming a paste, for example, due to relative reduction in amount of the organic vehicle. For example, the silver powder may be present in an amount of about 70 wt % to about 90 wt %. In one embodiment, the silver powder may be present in an amount of about 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt %.

(B) Glass Frit

The glass frits may serve to enhance adhesion between the conductive powder and the wafer and to form silver crystal grains in an emitter region by etching the anti-reflection film and melting the silver powder, and may reduce contact resistance during the baking process of the composition for electrodes. During the baking process, the glass frits may soften and may decrease the baking temperature.

When the area of the solar cell is increased in order to improve solar cell efficiency, there may be a problem of increase in solar cell contact resistance, and it may be necessary to minimize both serial resistance (Rs) and influence on the p-n junction. As the baking temperatures varies within a broad range with increasing use of various wafers having different sheet resistance, it may be desirable that the glass frits secure sufficient thermal stability to withstand a wide range of baking temperatures.

The glass fits may be formed of a silver (Ag) compound and a metal oxide. For example, the glass frits may be prepared by mixing, melting, and pulverizing a silver compound that may decompose into silver (Ag) ions at a temperature of 1000° C. or less and a metal oxide. The metal oxide may include at least one kind of metal oxide.

The silver compound may be an ionic compound, and may include silver cyanide (AgCN), silver nitrate (AgNO₃), silver halide (Ag—X), silver carbonate (Ag₂CO₃), silver sulfate (Ag₂SO₄), silver acetate, or a mixture thereof. In silver halide (Ag—X), X may be iodine, fluorine, chlorine, or bromine, for example, iodine.

In one embodiment, the metal oxide may include one or more of lead (Pb) oxide or bismuth (Bi) oxide.

In an embodiment, the metal oxide may further include at least one metal oxide selected from oxides of tellurium (Te), phosphorus (P), germanium (Ge), gallium (Ga), cerium (Ce), iron (Fe), lithium (Li), silicon (Si), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), and aluminum (Al).

The glass frits may include silver (Ag) and tellurium (Te). In the electrode prepared by printing and baking the composition for solar cell electrodes including the glass frit, a mole ratio of Ag to Te may range from about 1:0.1 to about 1:25. Within this range, it may be possible to secure low serial resistance and low contact resistance.

In an embodiment, the glass fits may include one or more of phosphorus (P), germanium (Ge), gallium (Ga), cerium (Ce), iron (Fe), lithium (Li), silicon (Si), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

The glass frits may contain about 0.1 mole % to about 50 mole % of elemental silver, for example, about 0.5 mole % to about 40 mole % of elemental silver, based on the total mole of the glass fits.

The content of each metal component included in the glass fits may be measured by Inductively Coupled Plasma-Optical Emission Spectrometry (ICP-OES). The ICP-OES uses a very small amount of sample, and may shorten sample set-up time and reduce error, for example, due to pre-treatment of the sample, while providing excellent analytical sensitivity.

The ICP-OES may include pre-treating a sample, preparing a standard solution, and calculating the content of each metal component in the glass fits by measuring and converting the concentration of a metal component to be measured, and accurate measurement of the content of each metal component in the glass fit may be possible.

In operation of pre-treating a sample, a predetermined amount of the sample may be dissolved in an acid solution capable of dissolving an analysis target, i.e. each of the metal components in a sample glass fit, and then heated for carbonization. The acid solution may include a sulfuric acid (H₂SO₄) solution.

The carbonized sample may be diluted with a solvent, such as distilled water or hydrogen peroxide (H₂O₂), to an appropriate extent that may allow analysis of the analysis target. In view of element detection capability of an ICP-OES tester, the carbonized sample may be diluted to about 10,000 times.

In measurement with the ICP-OES tester, the pre-treated sample may be calibrated using a standard solution, for example, a standard solution of a metal component to be analyzed for measuring elements.

By way of example, calculation of the content and mole ratio of each metal component in the glass frits may be accomplished by introducing the standard solution into the ICP-OES tester and plotting a calibration curve with an external standard method, followed by measuring and converting the concentration (ppm) of an analysis target in the pre-treated sample using the ICP-OES tester.

The glass frits may be prepared from the silver compound and metal oxide as set forth above by a method known in the art. For example, the silver compound and the metal oxide may be mixed in a predetermined ratio. Mixing may be carried out using a ball mill or a planetary mill. The mixture may be melted at 800° C. to 1300° C., followed by quenching to 25° C. The obtained resultant product may be subjected to pulverization using, for example, a disk mill or a planetary mill, and a glass fit may be prepared.

The glass fits may have an average particle diameter (D50) of about 0.1 μm to about 10 μm, and may have a spherical or amorphous shape.

The glass fits may be present in an amount of about 0.1 wt % to about 20 wt % based on the total weight of the composition for solar cell electrodes. Within this range, it may be possible to secure p-n junction stability given varying sheet resistance while minimizing serial resistance, and solar cell efficiency may be improved. For example, the glass fits may be present in an amount of about 0.5 wt % to about 10 wt %. In one embodiment, the glass fits may be present in an amount of about 0.1 wt %, 0.5 wt %, 1 wt %, 1.5 wt %, 2 wt %, 2.5 wt %, 3 wt %, 3.5 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %.

(C) Organic Vehicle

The organic vehicle may impart suitable viscosity and rheological characteristics for printing to the composition for solar cell electrodes through mechanical mixing with the inorganic component of the composition.

The organic vehicle may be an organic vehicle used in a composition for solar cell electrodes, and may include, for example, a binder resin and a solvent.

The binder resin may be selected from acrylate resins or cellulose resins. Ethyl cellulose may be used as the binder resin. The binder resin may be selected from, for example, ethyl hydroxyethyl cellulose, nitrocellulose, blends of ethyl cellulose and phenol resins, alkyd, phenol, acrylate ester, xylene, polybutane, polyester, urea, melamine, vinyl acetate resins, wood rosin, and polymethacrylates of alcohols.

The solvent may be selected from, for example, hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, ethyl lactate, and combinations thereof.

The organic vehicle may be present in an amount of about 1 wt % to about 30 wt % based on the total weight of the composition for solar cell electrodes. Within this range, the organic vehicle may provide sufficient adhesive strength and excellent printability to the composition. In one embodiment, the organic vehicle may be present in an amount of about 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %.

(D) Additives

The composition may further include additives to enhance fluidity and process properties and stability. The additives may include, for example, dispersants, thixotropic agents, plasticizers, viscosity stabilizers, anti-foaming agents, pigments, UV stabilizers, antioxidants, and coupling agents. These additives may be used alone or as mixtures thereof.

These additives may be present in an amount of about 0.1 wt % to about 5 wt % based on the total weight of the composition for solar cell electrodes. The content of the additives may be changed. In one embodiment, the additives may be present in an amount of about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 1.5 wt %, 2 wt %, 2.5 wt %, 3 wt %, 3.5 wt %, 4 wt %, 4.5 wt %, or 5 wt %.

A preliminary process of preparing a rear electrode may be performed by printing a composition for solar cell electrodes on a back surface of a p-n junction substrate and drying the printed composition at about 200° C. to about 400° C. for about 10 seconds to 60 seconds. A preliminary process for preparing a front electrode may be performed by printing the composition for electrodes on a front surface of the p-n junction substrate and drying the printed composition. Then, the front electrode and the rear electrode may be formed by baking at about 400° C. to about 950° C., for example, at about 750° C. to about 950° C., for about 30 seconds to 180 seconds.

The following Examples and Comparative Example are provided in order to highlight characteristics of one or more embodiments, but it will be understood that the Examples and Comparative Example are not to be construed as limiting the scope of the embodiments, nor is the Comparative Example to be construed as being outside the scope of the embodiments. Further, it will be understood that the embodiments are not limited to the particular details described in the Examples and Comparative Example.

Examples 1 to 7 and Comparative Example 1:

Preparation of Composition for Solar Cell Electrodes

### Example 1

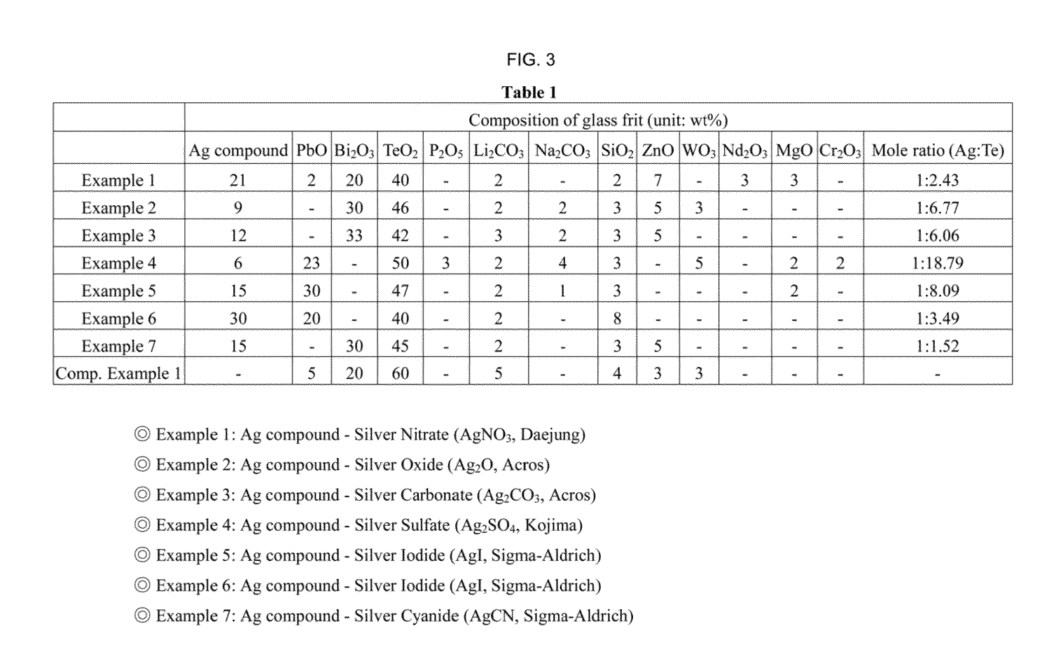

As an organic binder, 3.0 wt % of ethylcellulose (STD4, Dow Chemical Company) was sufficiently dissolved in 6.5 wt % of butyl carbitol at 60° C., and 86.90 wt % of spherical silver powder (AG-4-8, Dowa Hightech Co., Ltd.) having an average particle diameter of 2.0 μm, 3.1 wt % of glass fits prepared according to the composition as listed in Table 1 (see FIG. 3) using AgNO₃ as a silver compound, 0.2 wt % of a dispersant BYK102 (BYK-Chemie), and 0.3 wt % of a thixotropic agent Thixatrol ST (Elementis Co., Ltd.) were added to the binder solution, followed by mixing and kneading in a 3-roll kneader, thereby preparing a composition for solar cell electrodes.

### Examples 2 to 7

Compositions for solar cell electrodes were prepared in the same manner as in Example 1 except that the glass frits were prepared according to the compositions as listed in Table 1 (see FIG. 3).

### Comparative Example 1

A composition for solar cell electrodes was prepared in the same manner as in Example 1 except that the glass fits were prepared according to the composition as listed in Table 1 (see FIG. 3).

Measurement of Mole Ratio of Ag:Te in Glass Fit Using ICP-OES

Pretreatment of samples: 0.5 g of a glass frit sample to be analyzed was placed in a beaker and correctly weighed to 0.0001 g. 5 ml of sulfuric acid (H₂SO₄) was added to the beaker, followed by heating at 220° C. for about 3 hours using a hot plate, thereby completely carbonizing the sample. Hydrogen peroxide (H₂O₂) was added to the beaker until the beaker containing the carbonized sample became transparent, thereby completing pretreatment.

Preparation of standard solution: Respective standard solutions of metal components to be analyzed were prepared.

Measurement of mole ratio of metal components: Nitric acid (HNO₃) was added to the beaker containing the pre-treated sample, followed by heating for 5 minutes and air-cooling. The prepared standard solution was introduced into an ICP-OES tester (PerkinElmer, Inc.), and a calibration curve was plotted by an external standard method, followed by measuring and converting the elemental concentration (ppm) of silver (Ag) and tellurium (Te) in the sample using the ICP-OES tester, thereby calculating the mole ratio of Ag:Te in the glass frit. Results are shown in Table 1 (see FIG. 3).

Content of each metal component (%)=Elemental concentration of each metal component (ppm)×Dilution Factor (DF)/10000

Mole of each metal component=Content of each metal component/Molecular weight of each metal component

Mole % of each metal component=Mole of each metal component/Total mole of all metal components

Measurement Method of Fill Factor and Conversion Efficiency

Each of the compositions prepared in the Examples and Comparative Example was deposited over a front surface of each of crystalline monolayer wafers having different sheet resistance as shown in Table 2 by screen printing in a predetermined pattern, followed by drying in an IR drying furnace. Then, an aluminum paste was printed on a back surface of the wafer and dried in the same manner as above. Cells formed according to this procedure were subjected to baking at 600° C. to 1000° C. for 30 seconds to 180 seconds in a belt-type baking furnace, and evaluated as to open circuit voltage (Voc), serial resistance (Rs), and conversion efficiency (%) using a solar cell efficiency tester CT-801 (Pasan Co., Ltd.). Results are shown in Table 2.

TABLE 2

| Sheet resistance | | | | |
|---|---|---|---|---|
| of wafer | | | | Conversion |
| (Ω/sq) | Composition | Voc (mV) | Rs (mΩ) | efficiency (%) |
| 92.3 | Example 1 | 624.45 | 2.7377 | 17.45 |
| | Example 2 | 625.01 | 2.6389 | 17.51 |
| | Example 3 | 624.91 | 2.5951 | 17.48 |
| | Example 4 | 625.79 | 2.5897 | 17.41 |
| | Example 5 | 625.17 | 2.6596 | 17.41 |
| | Example 6 | 625.03 | 2.5225 | 17.50 |
| | Example 7 | 625.74 | 2.6961 | 17.49 |
| | Comparative | 624.63 | 3.1763 | 17.30 |
| | Example 1 | | | |
| 100.5 | Example 1 | 631.19 | 3.0458 | 17.78 |
| | Example 2 | 627.67 | 3.2709 | 17.77 |
| | Example 3 | 630.02 | 3.0813 | 17.76 |
| | Example 4 | 629.10 | 3.0677 | 17.72 |
| | Example 5 | 630.19 | 3.1547 | 17.76 |
| | Example 6 | 628.78 | 3.1636 | 17.77 |
| | Example 7 | 627.50 | 3.1555 | 17.75 |
| | Comparative | 629.64 | 4.1676 | 17.39 |
| | Example 1 | | | |
| 122.4 | Example 1 | 635.34 | 3.8018 | 17.81 |
| | Example 2 | 633.00 | 3.4253 | 17.83 |
| | Example 3 | 632.90 | 3.7588 | 17.83 |
| | Example 4 | 633.85 | 3.5418 | 17.83 |
| | Example 5 | 632.33 | 3.6809 | 17.89 |
| | Example 6 | 634.97 | 3.8582 | 17.85 |
| | Example 7 | 632.52 | 3.5132 | 17.87 |
| | Comparative | 634.42 | 6.4005 | 17.11 |
| | Example 1 | | | |

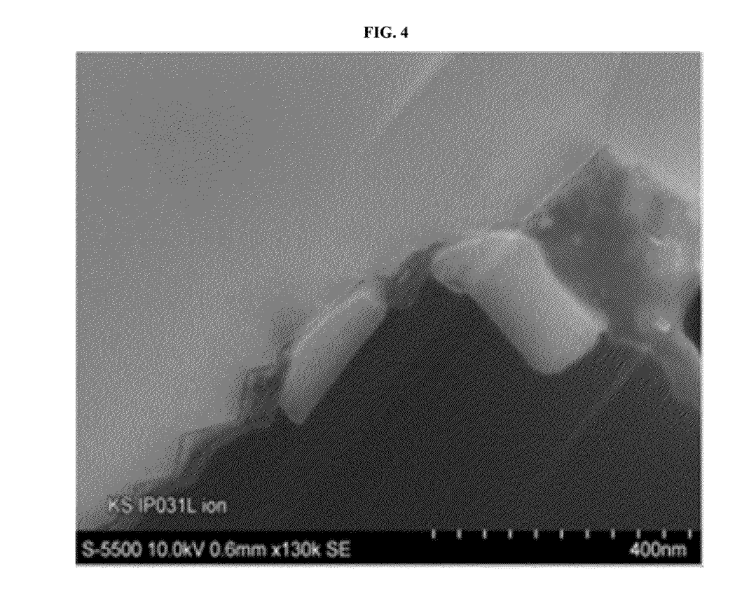

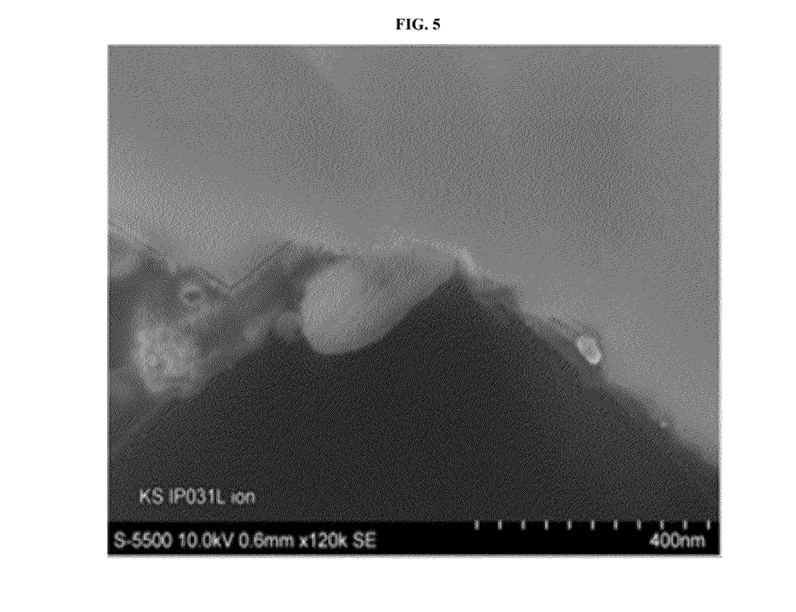

FIG. 4 illustrates an SEM image of a silver crystal formed within an electrode on a high sheet resistance wafer having a sheet resistance of 92.3 Ω/sq, in which the electrode was formed of a composition prepared in Example 1. FIG. 5 illustrates an SEM mage of a silver crystal formed within an electrode on a high sheet resistance wafer having a sheet resistance of 100.5 Ω/sq, in which the electrode was formed of the composition prepared in Example 1.

As shown in Table 2, the electrodes formed on the p-n junction substrate having a high sheet resistance of 85 Ω/sq to 150 Ω/sq using the compositions of Examples 1 to 7 including the glass frits in which a mole ratio of Ag:Te ranges from 1:0.1 to 1:25 had low serial resistance and exhibited excellent fill factor and conversion efficiency as compared with the electrode prepared using the composition including the glass frits without any silver.

By way of summation and review, continuous reduction in emitter thickness for improvement of solar cell efficiency may cause shunting, which may deteriorate solar cell performance. An area of a solar cell may be gradually increased to achieve high efficiency. However, there may be a problem of efficiency deterioration, for example, due to increase in contact resistance of the solar cell.

Therefore, there may be a need for a composition for solar cell electrodes that may enhance contact efficiency between the electrodes and the wafer to minimize contact resistance (Rc) and serial resistance (Rs), and provide excellent conversion efficiency.

Provided is a solar cell that may exhibit excellent contact efficiency between an electrode and a surface of a wafer. Provided is a solar cell that may exhibit minimized contact resistance and serial resistance. Provided is a solar cell that may have excellent fill factor and conversion efficiency.

Provided is a solar cell that may include an electrode on a high sheet resistance substrate. The electrode may be formed of a composition for solar cell electrodes including a glass frit originating from a silver compound that may decompose into silver (Ag) ions at a temperature of 1000° C. or less, in order to enhance contact efficiency between the electrode and the substrate, and may have high open circuit voltage (Voc) and minimized contact resistance (Rc) and serial resistance (Rs), and excellent fill factor and conversion efficiency may be provided.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a p-n junction substrate; and
an electrode on one surface of the p-n junction substrate,
wherein:
the p-n junction substrate has a sheet resistance of about 85 Ω/sq to about 150 Ω/sq, and
a silver (Ag) crystal having a particle diameter of about 10 nm to about 1,000 nm is present within the electrode adjacent to an interface between the p-n junction substrate and the electrode.

2. The solar cell as claimed in claim 1, further comprising:
an anti-reflection film and a front electrode sequentially formed on a front surface of the p-n junction substrate; and
a back surface field layer and a rear electrode sequentially formed on a back surface of the p-n junction substrate.

3. The solar cell as claimed in claim 1, wherein the p-n junction substrate includes one surface of a p-type substrate doped with an n-type dopant to form an n-type emitter.

4. The solar cell as claimed in claim 1, wherein the p-n junction substrate includes one surface of an n-type substrate doped with a p-type dopant to form a p-type emitter.

5. The solar cell as claimed in claim 1, wherein the p-n junction substrate has a textured structure on a front surface thereof.

6. The solar cell as claimed in claim 1, wherein the electrode is prepared from a composition for solar cell electrodes, the composition including silver (Ag) powder; a glass frit containing elemental silver (Ag) and elemental tellurium (Te); and an organic vehicle, a mole ratio of Ag to Te ranging from about 1:0.1 to about 1:25 in the glass frit.

7. The solar cell as claimed in claim 6, wherein the elemental silver (Ag) originates from at least one silver compound selected from a silver cyanide, silver nitrate, silver halide, silver carbonate, silver sulfate, and silver acetate.

8. The solar cell as claimed in claim 6, wherein the glass fit contains about 0.1 mole % to about 50 mole % of the elemental silver (Ag) based on a total mole of the glass frit.

9. The solar cell as claimed in claim 6, wherein the glass fit has an average particle diameter (D50) of about 0.1 μm to about 10 μm.
